(19) United States
(12) Patent Application Publication
(10) Pub. No.: US 2002/0155218 A1
(43) Pub. Date: Oct. 24, 2002

(54) Process for uniformly coating hollow bodies

(76) Inventors: Rolf Meyer, Bad Gandersheim (DE); Dieter Fischer, Bad Gandersheim (DE); Lutz Zogg, Bad Gandersheim (DE)

Correspondence Address: FULBRIGHT & JAWORSKI, LLP, 666 FIFTH AVE, NEW YORK, NY, 10103-3198, US

(21) Appl. No.: 10/126,350

(22) Filed: Apr. 19, 2002

(30) Foreign Application Priority Data
Apr. 21, 2001 (DE) 101 19 571.0

(51) Int. Cl. B05D 7/22; C23C 16/00

(52) U.S. Cl. 427/255.28; 427/569; 427/237

(57) ABSTRACT

The present invention relates to a process for uniformly coating hollow bodies, in which one open end of the hollow body is closed off in a gas-tight manner by a cover, the hollow body is introduced into a plasma-induced CVD reactor, vacuum is applied to the hollow body, a coating temperature is established and the plasma-induced coating takes place. The present invention also relates to the use of the process for uniformly coating hollow bodies according to the invention for coating tubes, vessels, syringe bodies, reflectors, domes and funnels.

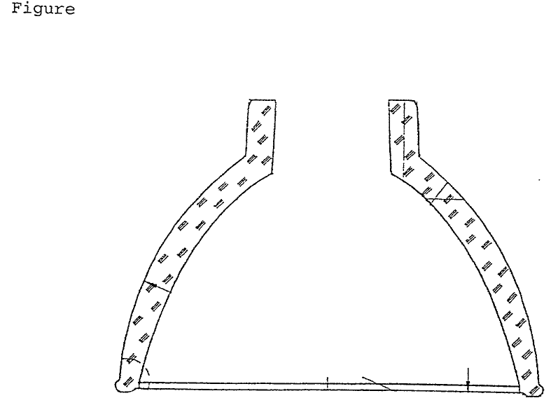

### BACKGROUND OF THE INVENTION

In many coating processes, it is necessary to use an elevated temperature and to apply a vacuum. New coating processes, such as the plasma-induced CVD process, have proven to be very well suited in particular to the coating of glasses and plastics. For this purpose, a vitreous hollow body, such as a dome, is placed into a reactor. In the inner region of the hollow body, a vacuum of approximately 10⁻⁹ bar is generated. To generate the vacuum, one end of the dome has to be closed. The end of the dome where the burner is subsequently fitted, i.e., at the neck, usually remains closed off by a glass base. A temperature of approximately 180° C. is generated in the interior of the dome. In the reactor, a field in the microwave range is applied and, at the same time, a precursor gas, such as hexamethyldisiloxane and oxygen, is introduced into the interior of the dome. This process causes an SiO₂ layer to be applied to the inner surface of the interior of the dome. The coated domes are then tempered until a set elevated temperature is reached.

The process described is suitable for coating all possible hollow bodies, such as tubes, reflectors, bottles, ampoules, syringe bodies and vessels. The hollow bodies can be coated with different layers. It is preferable for the surfaces to be coated with virtually any metal oxide, such as SiO₂, TiO₂, SnO₂, Al₂O₃ and similar oxides.

In the coating processes described, at least one end has to be closed in order to apply a vacuum. Leaks would impair the durability of the layers. If one end is closed off by a glass base, a very large quantity of glass is formed within a small area. When the hollow body is heated, the glass base is heated more quickly.

To reach a required working temperature at every point on the surface which is to be coated, the hollow body has to be heated for longer.

In the case of a closed hollow body, cleaning before coating is very difficult and incomplete. Prior cleaning of the surface is indispensable, since a smooth substrate is required for the coating. A further drawback of the conventional process is the separation of the glass base by means of sawing which is required after coating has taken place, and the subsequent cleaning of the surface. Even openings can be made after the coating has taken place.

### OBJECTS AND SUMMARY OF THE INVENTION

It is an object of the present invention or provide an economical, environmentally friendly process for uniformly coating hollow bodies.

The object of the present invention is achieved by a process for uniformly coating hollow bodies, in which one open end of the hollow body is closed off in a gas-tight manner by a cover, the hollow body is introduced into a plasma-induced CVD reactor, vacuum is applied to the hollow body, a coating temperature is established and the plasma-induced coating takes place.

The cover for sealing the hollow body and the glass substrate results in significant advantages. At the time of coating, the glass substrate is vacuum-tight. The glass substrate can be heated uniformly for the coating and therefore has a homogenous temperature distribution. The processing time and manufacturing costs are reduced. The hollow body is very easy to clean before the coating, since it has two openings. This makes the coating more uniform, results in a lower scatter in the uniformity and leads to a higher layer adhesion.

In accordance with a preferred configuration of the invention, the cover comprises at least one plastic. The use of the plastic cover of this type during the coating process leads to good results.

In accordance with a particularly preferred configuration of the present invention, the cover comprises at least one silicone rubber. Particularly good coating results were achieved using a silicone hood or cover of this type.

In accordance with an embodiment of the present invention, the inventive process is used for coating tubes, vessels, syringe bodies, reflectors, domes and funnels.

### BRIEF DESCRIPTION OF THE DRAWING

The drawing comprises one FIGURE, which shows a longitudinal section through a dome in which the glass base is cut off at the neck.

### DETAILED DESCRIPTION OF THE EMBODIMENT

The invention is explained in more detail with reference to a drawing and examples.

### EXAMPLE

On a conventional dome with a diameter of 5.5 cm, the glass base was sawn off on the outer side. The dome which was open at both ends was thoroughly washed and dried. One open end was closed in a gas-tight manner by a silicone stopper. The dome was introduced, with the open end facing downward, into a plasma-induced CVD reactor. A vacuum of 0.7*10⁻⁹ bar was applied in the reactor. A temperature of 180° C. was established. Then, layers of SiO₂, starting from hexamethyldisiloxane in combination with oxygen, and layers of TiO₂ were applied alternatively. A total of 33 layers were applied. First of all, a thin SiO₂ layer was applied, and the final layer applied was a thick SiO₂ layer. Between these layers, the coating alternated. The total time required for coating was 6 minutes. A homogeneous layer distribution between neck and flange of the dome was achieved. Uniform layer distribution was observed.

### COMPARATIVE EXAMPLE

The process was carried out as in the example, except that the glass base was not sawn off. The closed dome was washed thoroughly and dried, with every great difficulty. The dome was introduced into a plasma-induced CVD reactor. A vacuum of 0.7*10⁻⁹ bar was applied in the reactor. A temperature of 180° C. was established. Then, layers of SiO₂, starting from hexamethyldisiloxane in combination with oxygen, and layers of TiO₂ were applied alternately. A total of 33 layers were applied, and the final layer applied was a thick SiO₂ layer. Between these layers, the coating alternated. The total time required for the coating was 7 minutes. An inhomogeneous layer distribution between neck and flange of the dome was achieved. The layer was thinner at the neck than at the flange. This is related to the inhomogeneous temperature distribution. An uneven layer distribution was observed. The glass base then had to be carefully removed, with difficulty, by sawing, and the dome had to be cleaned again.

1. A process for uniformly coating hollow bodies, in which
a) one open end of the hollow body is closed off in a gas-tight manner by a cover,
b) the hollow body is introduced into a plasma-induced CVD reactor,
c) vacuum is applied to the hollow body, a coating temperature is established and plasma-induced coating takes place.

2. The process as claimed in claim 1, in which the cover comprises at least one plastic.

3. The process as claimed in claim 1 or 2, in which the cover contains at least one silicone rubber.

4. The use of the process for uniformly coating hollow bodies as claimed in one or more of claim 1 to 3 for coating tubes, vessels, syringe bodies, reflectors, domes and funnels.
